(19) United States
(12) Patent Application Publication
(10) Pub. No.: US 2026/0293181 A1
(43) Pub. Date: Sep. 24, 2026

(54) SEMICONDUCTOR DEVICE AND MANUFACTURING METHOD FOR SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Hitoshi KOBAYASHI, Yamato Kanagawa (JP); Yorito KAKIUCHI, Yokohama Kanagawa (JP); Ken HIROSE, Kawasaki Kanagawa (JP)

(21) Appl. No.: 19/395,530

(22) Filed: Nov. 20, 2025

(30) Foreign Application Priority Data
Mar. 21, 2025 (JP) 2025-046473

(51) Int. Cl. H10D 30/47; H10D 30/01; H10D 62/824; H10D 64/00; H10D 64/27

(52) U.S. Cl. CPC H10D 30/475; H10D 30/015; H10D 62/824; H10D 64/112; H10D 64/518; H10D 30/476

(57) ABSTRACT

A semiconductor device according to an embodiment includes a semiconductor layer, a first insulating film provided on the semiconductor layer, a first electrode provided on the first insulating film, a second electrode provided on the semiconductor layer, a third electrode provided on the semiconductor layer, and a nitride film provided on the semiconductor layer on the second electrode side between the first electrode and the second electrode. The nitride film includes a step-like portion on the first electrode. The nitride film and the first insulating film are arranged in a stacking direction of the semiconductor layer and the first electrode. The nitride film includes a portion which is in direct contact with the semiconductor layer. A part of the step-like portion is physically separated from the first insulating film in the stacking direction.

### CROSS-REFERENCE TO RELATED APPLICATION

This application is based upon and claims the benefit of priority from Japanese Patent Application No. 2025-046473, the Filing Date of which is Mar. 21, 2025, the entire contents of which are incorporated herein by reference.

### FIELD

Embodiments described herein relate generally to a semiconductor device and a manufacturing method for a semiconductor device.

### BACKGROUND

Semiconductor devices such as transistors and diodes are used in circuits such as switching power supply circuits and inverter circuits. These semiconductor devices are desired to have high breakdown voltage and low on-resistance.

### BRIEF DESCRIPTION OF THE DRAWINGS

FIG. 1 is a schematic cross-sectional diagram of a semiconductor device according to an embodiment;

FIG. 2 is a schematic top-view diagram of a semiconductor device according to an embodiment;

FIG. 3 is a schematic cross-sectional diagram of a semiconductor device according to an embodiment;

FIG. 4 is a schematic cross-sectional diagram of a semiconductor device according to an embodiment;

FIG. 5 is a schematic cross-sectional diagram of a semiconductor device according to an embodiment;

FIG. 6 is a schematic cross-sectional diagram of a semiconductor device according to an embodiment;

FIG. 7 is a schematic cross-sectional diagram of a semiconductor device according to an embodiment;

FIG. 8 is a schematic cross-sectional diagram of a semiconductor device according to an embodiment;

FIG. 9 is a schematic cross-sectional diagram of a semiconductor device according to an embodiment;

FIG. 10 is a flowchart of a manufacturing method for a semiconductor device according to an embodiment;

FIG. 11 is a schematic diagram relating to a manufacturing method for a semiconductor device according to an embodiment;

FIG. 12 is a schematic diagram relating to a manufacturing method for a semiconductor device according to an embodiment;

FIG. 13 is a schematic diagram relating to a manufacturing method for a semiconductor device according to an embodiment;

FIG. 14 is a schematic diagram relating to a manufacturing method for a semiconductor device according to an embodiment;

FIG. 15 is a schematic diagram relating to a manufacturing method for a semiconductor device according to an embodiment;

FIG. 16 is a schematic diagram relating to a manufacturing method for a semiconductor device according to an embodiment;

FIG. 17 is a schematic diagram relating to a manufacturing method for a semiconductor device according to an embodiment;

FIG. 18 is a schematic diagram relating to a manufacturing method for a semiconductor device according to an embodiment;

FIG. 19 is a schematic diagram relating to a manufacturing method for a semiconductor device according to an embodiment;

FIG. 20 is a schematic diagram relating to a manufacturing method for a semiconductor device according to an embodiment;

FIG. 21 is a schematic diagram relating to a manufacturing method for a semiconductor device according to an embodiment;

FIG. 22 is a schematic diagram relating to a manufacturing method for a semiconductor device according to an embodiment; and

FIG. 23 is a schematic cross-sectional diagram of a semiconductor device according to an embodiment.

### DETAILED DESCRIPTION

A semiconductor device according to an embodiment includes a semiconductor layer, a first insulating film provided on the semiconductor layer, a first electrode provided on the first insulating film, a second electrode provided on the semiconductor layer, a third electrode provided on the semiconductor layer, and a nitride film provided on the semiconductor layer on the second electrode side between the first electrode and the second electrode. The nitride film includes a step-like portion on the first electrode. The nitride film and the first insulating film are arranged in a stacking direction of the semiconductor layer and the first electrode. The nitride film includes a portion which is in direct contact with the semiconductor layer. A part of the step-like portion is physically separated from the first insulating film in the stacking direction.

Hereafter, embodiments of the present invention will be described with reference to the drawings. Note that in the following description, the same or similar members are denoted by the same reference numeral(s), and the description of a member already explained may be omitted.

In this specification, "nitride semiconductor layer" includes "GaN-based semiconductor." " GaN-based semiconductor" refers to a general term for semiconductors comprising gallium nitride (GaN), aluminum nitride (AlN), indium nitride (InN), and intermediate compositions thereof.

In this specification, "undoped" means that the impurity concentration is 2 × 10¹⁶ [cm⁻³] or less.

To indicate the positional relationship of components, etc., the upward direction in the drawings will be described as "up" or the like and the downward direction will be described as "down", "bottom" or the like. The concepts of "up" and "down" in this specification do not necessarily represent the direction of gravity.

The physical properties mentioned in the specification are values under an atmospheric environment at 25 [° C]. The physical property values described for semiconductor devices also represent the physical property values for the method of manufacturing semiconductor devices. The physical property values described in the method of manufacturing semiconductor devices also represent the physical property values for semiconductor devices.

### First Embodiment

This first embodiment relates to a semiconductor device and a manufacturing method for the semiconductor device. The semiconductor device of the first embodiment includes a semiconductor element having a semiconductor layer, and a wiring layer provided on the semiconductor element. Hereinafter, an example using a GaN-based semiconductor device will be described, but the semiconductor element may be a lateral transistor other than a GaN-based transistor.

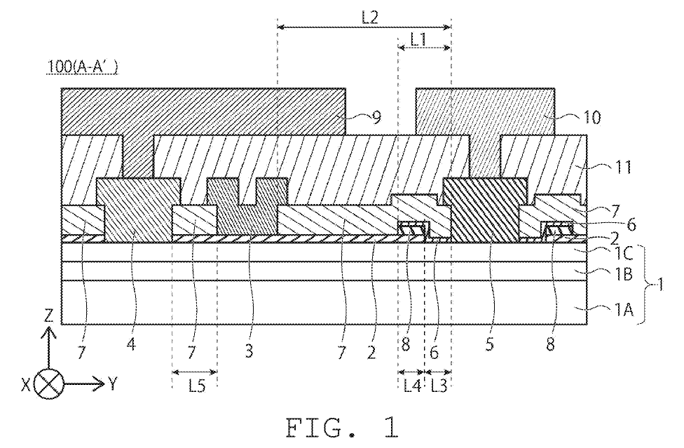

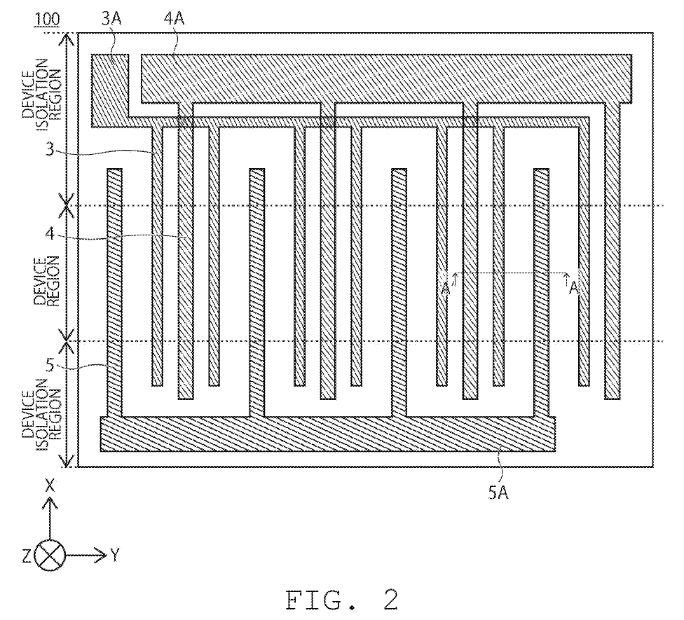

FIG. 1 is a schematic cross-sectional diagram of the semiconductor device 100 according to the first embodiment. FIG. 2 shows a schematic top-view diagram of the semiconductor device 100. FIG. 2 illustrates a schematic cross-sectional diagram along line A–A’ of FIG. 1. The semiconductor device 100 is, for example, a HEMT (High Electron Mobility Transistor) using a GaN-based semiconductor. The semiconductor device 100 includes a device region that operates as a transistor and a device isolation region that does not operate as a transistor.

As shown in FIG. 1, the semiconductor device 100 includes a semiconductor layer 1, a first insulating film 2 provided on the semiconductor layer 1, a first electrode 3 provided on the first insulating film 2, a second electrode 4 provided on the semiconductor layer 1, a third electrode 5 provided on the semiconductor layer 1, a nitride film 6 provided on the semiconductor layer 1, a second insulating film 8, a third insulating film 7, a first field plate electrode 9, a second field-plate electrode 10, and a fourth insulating film 11.

The semiconductor layer 1 includes, for example, a substrate 1A, a channel layer 1B (a first nitride semiconductor layer), and a barrier layer 1C (a second nitride semiconductor layer) stacked in that order. The semiconductor layer 1 includes a device region (active region) and a device isolation region. As shown in FIG. 2, the device isolation region (inactive region) is provided from the surface of the barrier layer 1C on the upper and lower sides of the semiconductor layer 1 toward the substrate 1A direction. The region where the device isolation region is not provided is the device region.

For example, the substrate 1A can be formed from silicon (Si). Alternatively, sapphire (Al₂O₃) or silicon carbide (SiC) can also be used.

It is preferable that a buffer layer be provided between the substrate 1A and the channel layer 1B. The buffer layer has a function of relaxing lattice mismatch between the substrate 1A and the channel layer 1B. For example, the buffer layer can be formed as a multilayer structure of aluminum gallium nitride (AlₓGa₁₋ₓN (0 < x ≤ 1)).

The channel layer 1B is provided on the substrate 1A or on the buffer layer. The channel layer 1B is also called an electron transport layer. For example, the channel layer 1B can be undoped aluminum gallium nitride (AlxGa1-xN (0 ≤ x < 1)). More specifically, for example, the channel layer 1B can be undoped gallium nitride (GaN). The thickness of the channel layer 1B is, for example, 0.1 [μm] or more and 10 [μm] or less. In the embodiment, the thickness refers to the length (height) of each member in the third direction (Z-direction), which is the stacking direction including the channel layer 1B and the barrier layer 1C.

The barrier layer 1C is provided on the channel layer 1B. The barrier layer 1C is also called an electron supply layer. The bandgap of the barrier layer 1C is larger than the bandgap of the channel layer 1B. For example, the barrier layer 1C is undoped aluminum gallium nitride (Al_{Y}Ga_{x-y}N (0 < Y ≤ 1, X < Y)). More specifically, for example, the barrier layer 1C is undoped Al_{0.25}Ga_{0.75}N. The thickness of the barrier layer 1C is, for example, 2 [nm] or more and 100 [nm] or less.

A heterojunction interface is formed between the channel layer 1B and the barrier layer 1C. A two-dimensional electron gas (2DEG) is formed at the heterojunction interface and electrons in the 2DEG work a carrier of the semiconductor device 100.

The isolation region is a high-resistance region formed by ion implantation. The high-resistance region will be described in the second embodiment. The isolation region is formed, for example, at least inside the channel layer 1B. Ion species used for isolation include, for example, nitrogen or argon. The dose amount accompanying ion implantation is, for example, about 1 × 10¹⁴ [ions/cm²]. The acceleration energy during ion implantation is, for example, 100 [keV] or more and 200 [keV] or less. The region where the isolation region is formed (the boundary between the isolation region and the device region) can be confirmed by cross-sectional observation using a transmission electron microscope (TEM), for example.

A gate insulating film which is the first insulating film 2 (hereinafter, referred to as "the gate insulating film 2") is provided between the first electrode 3 and the barrier layer 1C, making the semiconductor device 100 an MIS (Metal Insulator Semiconductor) type HEMT. The gate insulating film 2 is located between the second electrode 4 and the third electrode 5. For example, the gate insulating film 2 is an oxide or oxynitride. The gate insulating film 2 is, for example, silicon oxide (SiO₂), silicon nitride (SiN), aluminum oxide, silicon oxynitride, or aluminum oxynitride. The gate insulating film 2 is a dense insulating film. The gate insulating film 2 is denser than the second insulating film 8.

The density of the gate insulating film 2 is preferably 2 [g/cm³] or more and 3.16 [g/cm³] or less. The thickness of the gate insulating film 2 is, for example, 10 [nm] or more and 100 [nm] or less. The thickness of the gate insulating film 2 is preferably 10 [nm] or more and 300 [nm] or less, more preferably 100 [nm] or more and 300 [nm] or less, and even more preferably 100 [nm] or more and 200 [nm] or less.

The edge of the gate insulating film 2 on the side of the third electrode 5 is not in direct contact with the third electrode 5. Preferably, the edge of the gate insulating film 2 on the side of the third electrode 5 is in direct contact with the side surface of the step-like portion of the nitride film 6 on the side of the gate electrode 3.

Preferably, the surface of the gate insulating film 2 opposite the semiconductor layer 1 side is not in direct contact with the nitride film 6.

The first electrode (gate electrode) 3 is an electrode having a plurality of fingers extending in the first direction (X-direction). Each finger of the gate electrode 3 with a comb-shape extends in the first direction, and each finger is arranged in the second direction (Y-direction). The gate electrode 3 is provided on the first insulating film (gate insulating film) 2 provided on the channel layer 1B and the barrier layer 1C. The gate electrode 3 is electrically connected to the channel layer 1B and the barrier layer 1C. For example, the gate electrode 3 is in direct contact with the first insulating film 2. The gate electrode 3 is provided between the second electrode 4 and the third electrode 5. The gate electrode 3 is connected to a first electrode pad (gate electrode pad) 3A. The side of the gate electrode 3 opposite the semiconductor layer 1 may have a shape for a field plate electrode that mitigates electric field concentration. The gate electrode 3 and the semiconductor layer 1 are stacked in the Z-direction.

For example, the gate electrode 3 is titanium nitride (TiN).

The field plate electrode portion of the gate electrode 3 preferably includes one or more elements selected from the group consisting of Cu, Si, and Ti in addition to Al.

The second electrode (source electrode) 4 is an electrode having a plurality of fingers extending in the first direction. Each finger of the source electrode 4 with a comb-shape extends in the first direction, and each finger is arranged in the second direction (Y-direction). For example, the fingers of the source electrode 4 are sandwiched by the fingers of the gate electrode 3. The source electrode 4 is provided on the semiconductor layer 1, and more specifically, on the channel layer 1B and the barrier layer 1C. The source electrode 4 is electrically connected to the channel layer 1B and the barrier layer 1C. For example, the source electrode 4 or the first field-plate electrode 9 is connected to a second electrode pad (source electrode pad) 4A. When the first field-plate electrode 9 is connected to the second electrode pad 4A, for example, the source electrode 4 has only a finger portion shape. The source electrode 4 and the gate electrode 3 are arranged in parallel in the X direction.

For example, the source electrode 4 is a metal electrode. For example, the source electrode 4 is an aluminum film containing 50 [wt%] or more of aluminum, an aluminum alloy film containing 50 [wt%] or more of aluminum, or a laminated film of titanium (Ti) and aluminum (Al). It is desirable to form an ohmic contact between the source electrode 4 and the barrier layer 1C.

The semiconductor device 100 preferably includes a first field-plate electrode 9. Providing a field plate electrode can mitigate electric field concentration on the electrode. The first field-plate electrode 9 is a source field-plate electrode (hereinafter, "source FP electrode") connected to the source electrode 4. The source FP electrode 9 is positioned such that its center aligns with the center or near-center of the source electrode 4 in the stacking direction (Z-direction). and positioned above the source electrode 4 and the gate electrodes 3 to overlap the source electrode 4 and the gate electrodes which sandwich the source electrode 4.

The source FP electrode 9 is a conductive material including Al as a main component. It is preferable that the source FP electrode 9 includes 80 [wt%] or more of Al, more preferably 90 [wt%] or more of Al, even more preferably 95 [wt%] or more of Al, and most preferably 99 [wt%] or more of Al.

A source field-plate electrode not shown in the figures may be provided between the gate electrode 3 and the drain electrode 5. The non-shown source field-plate electrode is electrically connected to the source electrode 4 and mitigates electroluminescence concentration.

The third electrode (drain electrode) 5 is an electrode having a plurality of fingers extending in the first direction (X-direction). Each finger of the drain electrode 5 with a comb-shape extends in the first direction, and each finger is arranged in the second direction (Y-direction). The fingers of the drain electrode 5 are opposite to those of the source electrode 4, i.e., the source electrode 4 and the drain electrode 5 are facing each other. The drain electrode 5 is provided on the channel layer 1B and the barrier layer 1C. The drain electrode 5 is electrically connected to the channel layer 1B and the barrier layer 1C. For example, the drain electrode 5 is in contact with the barrier layer 1C. For example, the drain electrode 5 or a second field-plate electrode 10 (drain FP electrode) is connected to a third electrode pad (drain electrode pad) 5A. When the drain FP electrode 10 is connected to the third electrode pad 5A, for example, the drain electrode 5 has only a finger portion shape. The drain electrode 5 and the gate electrode 3 are arranged in parallel in the X direction.

The drain electrode 5 has a cross-section that becomes T-shaped eaves.

For example, the drain electrode 5 is a metal electrode. For example, the drain electrode 5 includes Al as a main component. For example, the drain electrode 5 is an aluminum film containing 50 [wt%] or more of aluminum, an aluminum alloy film containing 50 [wt%] or more of aluminum, or a laminated film of titanium (Ti) and aluminum (Al). It is desirable that an ohmic contact is formed between the drain electrode 5 and the barrier layer 1C.

The distance between the source electrode 4 and the drain electrode 5 is, for example, 5 [μm] or more and 30 [μm] or less.

It is also possible to structure the source electrode 4 and the drain electrode 5 so that they are in direct contact with the channel layer 1B.

The semiconductor device 100 preferably includes a second field-plate electrode 10. Providing a field plate electrode can mitigate electric field concentration on the electrode. The second field-plate electrode 10 is a drain field-plate electrode (hereinafter, "drain FP electrode") connected to the drain electrode 5. It is preferable that the drain FP electrode 10 is provided above the drain electrode 5.

The drain FP electrode 10 is a conductive material primarily composed of Al. It is preferable that the drain FP electrode 10 contains 80 [wt%] or more of Al, more preferably 90 [wt%] or more of Al, even more preferably 95 [wt%] or more of Al, and most preferably 99 [wt%] or more of Al.

The nitride film 6 is provided on the semiconductor layer 1 on the drain electrode 5 side between the gate electrode 3 and the drain electrode 5. The nitride film 6 is in direct contact with the semiconductor layer 1. It is preferable that the nitride film 6 is in direct contact with the drain electrode 5. Furthermore, the nitride film 6 is provided between the semiconductor layer 1 and the third insulating film 7. The nitride film 6 has a step-like portion on the gate electrode 3 side. The nitride film 6 is a nitride film including aluminum or aluminum and gallium. For example, the nitride film 6 is Al_{z}Ga_{1-z}N (0< z ≤ 1)).

The step-like portion of the nitride film 6 in the diagram of FIG. 1 extends in the stacking direction of the semiconductor layer 1 and the gate electrode 3, and further follows the side shape of the gate insulating film 2 on the drain electrode 5 side (preferably, the step-like portion of the nitride film 6 is directly in contact with and aligned with the side of the gate insulating film 2 on the drain electrode 5 side). For example, the portion of the nitride film 6 that follows the side of the gate insulating film 2 on the drain electrode 5 side includes one or more selected from the group consisting of a part extending in the stacking direction of the semiconductor layer 1 and the gate electrode 3, a part inclined with respect to the stacking direction of the semiconductor layer 1 and the gate electrode 3, and a part curved with respect to the stacking direction of the semiconductor layer 1 and the gate electrode 3. This inclined shape and curved shape are also included in the form where the nitride film 6 has the step-like portion.

The step-like portion of the nitride film 6 is a portion where the position of the surface of the nitride film 6 on the semiconductor layer 1 side is higher (the position of the surface of the nitride film 6 on the semiconductor layer 1 side is shifted in the opposite direction to the semiconductor layer 1) than the surface of the nitride film 6 in contact with the semiconductor layer 1. FIG. 1 illustrates a configuration of the step-like portion with a clear step, but the step-like portion may have a sloped shape where the position of the surface of the nitride film 6 on the semiconductor layer 1 side is gradually higher.

The height difference of the step-like portion of the nitride film 6 (in the stacking direction of the semiconductor layer 1 and the gate electrode 3, the distance between the upper surface of the gate insulating film 2 (facing in the opposite direction to the semiconductor layer 1 side) and the surface of the nitride film 6 on the step-like portion facing the upper surface of the gate insulating film 2) is preferably 1 or more times and 5 or less times thicker than the thickness of the gate insulating film 2, more preferably 1 or more times and 3 or less times, and even more preferably 1 or more times and 2 or less times. When the height difference of the step-like portion of the nitride film 6 is small, the gate insulating film 2 is prone to damage. When the height difference of the step-like portion of the nitride film 6 is too high, it will necessitate major changes in the design of the semiconductor device 100, making it undesirable for various reasons.

The nitride film 6 includes a portion that is in direct contact with the semiconductor layer 1 and, the step-like portion of the nitride film 6 is (physically) separated from the gate insulating film 2in the stacking direction of the semiconductor layer 1 and the gate electrode 3. More specifically, a portion where the surface of the gate insulating film 2 facing the nitride film 6 side and the surface of the step-like portion of the nitride film 6 facing the gate insulating film 2 are (physically) separated from each other in the stacking direction of the semiconductor layer 1 and the gate electrode 3 is included. Furthermore, more specifically, the entire surface of the gate insulating film 2 facing the nitride film 6 side is (physically) separated from the entire surface of the step-like portion of the nitride film 6 facing the gate insulating film 2 in the stacking direction of the semiconductor layer 1 and the gate electrode 3.

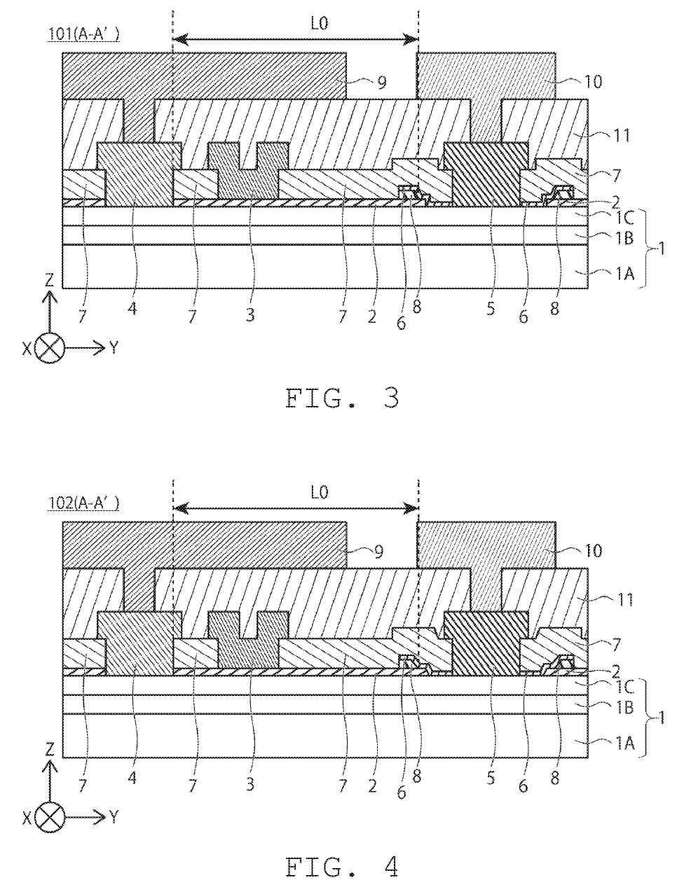

FIG. 3 shows a schematic diagram of semiconductor device 101. FIG. 4 shows a schematic diagram of semiconductor device 102. The schematic diagrams in FIGS. 3 and 4 are cross-sectional diagrams at the same positions as in FIG. 1. The semiconductor device 101 and the semiconductor device 102 are variations of the semiconductor device 100. In the stacking direction of the semiconductor layer 1 and the gate electrode 3 of semiconductor devices 101 and 102, the nitride film 6 on the gate electrode 3 side includes a portion X1 (not shown symbol in drawings) that rides up onto the gate insulating film 2 on the drain electrode 5 side, and optionally further includes a portion X2 (not shown symbol in drawings) separated from the gate insulating film 2 and located further on the gate electrode 3 side from the riding-up portion X1, preferably.

As shown in the schematic diagrams of FIGS. 3 and 4, as long as most of the upper surface of the gate insulating film 2 (facing the opposite direction to the semiconductor layer 1 side) is separated from the nitride film 6 in the stacking direction of the semiconductor layer 1 and the gate electrode 3, the nitride film 6 may be in direct contact with a portion on the drain electrode 5 side. It is preferable that the riding-up portion X1 and the separating portion X2 are directly adjacent to each other. There is a difference between the semiconductor device 101 and the semiconductor device 102. The riding-up portion X1 of the nitride film 6 extends in the stacking direction of the semiconductor layer 1 and the gate electrode 3 of semiconductor device 101. The portion of the nitride film 6 along the gate insulating film 2 in semiconductor device 102 is inclined in the stacking direction of the semiconductor layer 1 and the gate electrode 3.

The riding-up portion X1 of the nitride film 6 on the gate electrode 3 side where the nitride film 6 rides up on the gate insulating film 2 on the drain electrode 5 side is a portion where the surface of the gate electrode 3 opposite to the semiconductor layer 1 side is in direct contact with the nitride film 6. The portion where the gate electrode 3 is in direct contact with the nitride film 6 is located on the drain electrode 5 side of the gate insulating film 2. The semiconductor device 101 in FIG. 3 and the semiconductor device 102 in FIG. 4 include riding-up portions X1 instead of step-like portions, and optionally separated portions X2; however, except for explanations outside of those in FIGS. 3 and 4, the explanation of step-like portions may correspond to the explanation of riding-up portions X1 and optional separated portions X2.

It is preferable that the riding-up portion X1 of the nitride film 6 on the gate electrode 3 side where the nitride film 6 rides up on the gate insulating film 2 on the drain electrode 5 side be in direct contact (connected) with the nitride film 6 along the side surface of the gate electrode 3.

The length of the riding-up portion X1 in the direction where the gate electrode 3 and the drain electrode 5 are aligned is preferably more than 0% and 5% or less of a distance L2 between the end surface on the drain electrode 5 side of the gate electrode (bottom) 3 and the end surface on the gate electrode 3 side of the drain electrode (bottom) 5, more preferably more than 0% and 4% or less of the distance L2, and even more preferably more than 0% and 3% or less of the distance L2.

It is preferable that the length of the riding-up portion X1 in the direction where the gate electrode 3 and the drain electrode 5 is shorter than the length of a portion where the nitride film 6 and the semiconductor layer 1 are in direct contact with each other in the same direction. The length of riding-up portion X1 in the direction where the gate electrode 3 and the drain electrode 5 are aligned is preferably 0% or more and 50% or less of the length of a portion where the nitride film 6 and the semiconductor layer 1 are directly in contact with each other in the same direction, more preferably 0% to 30% or less, and even more preferably 0% to 20% or less.

The average distance of the separated portion X2 between the nitride film 6 and the gate insulating film 2 in the stacking direction of the semiconductor layer 1 and the gate electrode 3 is preferably 0.5 or more times and 5 or more times the thickness of the gate insulating film 2, more preferably 1 or more times and 3 or more times, and even more preferably 1 or more times and 2 or more times.

The portion where the nitride film 6 is along the side surface of the drain electrode 5 side of the gate insulating film 2 in the semiconductor devices 101 and 102 including the riding-up portion X1 are also includes one or more selected from the group consisting of a part extending in the stacking direction of the semiconductor layer 1 and the gate electrode 3, a part inclined with respect to the stacking direction of the semiconductor layer 1 and the gate electrode 3, and a part curved with respect to the stacking direction of the semiconductor layer 1 and the gate electrode 3.

The distance L0 between the most gate electrode 3 side position (starting point) where the nitride film 6 and the gate insulating film 2 are in direct contact to the end surface on the drain electrode 5 side of the gate electrode (bottom) 3 is preferably 90% or more of the distance L2 the end surface on the drain electrode 5 side of the gate electrode (bottom) 3 and the end surface on the gate electrode 3 side of the drain electrode (bottom) 5, preferably.

The step-like portion of the nitride film 6 is located on the gate electrode 3 side and covers a part of the gate insulating film 2. The nitride film 6 and the gate insulating film 2 are aligned in the stacking direction of the semiconductor layer 1 and the gate electrode 3. The step-like portion of the nitride film 6 is a portion physically separated from the gate insulating film 2 in the stacking direction of the semiconductor layer 1 and the gate electrode 3, preferably.

The nitride film 6 and the gate insulating film 2 is not in direct contact with each other in the stacking direction of the semiconductor layer 1 and the gate electrode 3, preferably. An insulating film is preferably provided between the nitride film 6 and the gate insulating film 2 in the stacking direction of the semiconductor layer 1 and the gate electrode 3. No conductive layer exists between the nitride film 6 and the gate insulating film 2 in the stacking direction of the semiconductor layer 1 and the gate electrode 3, preferably. The insulating film provided between the nitride film 6 and the gate insulating film 2 in the stacking direction of the semiconductor layer 1 and the gate electrode 3, is a film with a lower density than the gate insulating film 2, preferably. The insulating film with a lower density than the gate insulating film 2, for example, the second insulating film 8 or/and the third insulating film 7, is preferably provided between the nitride film 6 and the gate insulating film 2 in the stacking direction of the semiconductor layer 1 and the gate electrode 3, preferably.

The step-like portion of the nitride film 6 includes at least a portion extending in a direction opposite to the semiconductor layer 1 from the semiconductor layer 1 side. The step-like portion of the nitride film 6 to include a portion extending towards the gate electrode 3 side from the portion extending in the direction opposite to the semiconductor layer 1, preferably.

The nitride film 6 is in direct contact with the semiconductor layer 1 and the drain electrode 5, preferably. The nitride film 6 is directly adjacent to the drain electrode 5 in the direction where the gate electrode 3 and the drain electrode 5 are aligned, preferably. The end surface of the nitride film 6 on the drain electrode 5 side is in direct contact with the drain electrode 5, preferably.

The portion where the nitride film 6 is in direct contact with the semiconductor layer 1 is located between the gate insulating film 2 and the drain electrode 5 in the direction where the gate electrode 3 and the drain electrode 5 are aligned. The gate electrode 3 side of the portion where the nitride film 6 is in direct contact with the semiconductor layer 1 is directly adjacent to the gate insulating film 2, preferably. The portion where the nitride film 6 is in direct contact with the semiconductor layer 1 of the drain electrode 5 side to be directly adjacent to the drain electrode 5, preferably.

The surface of the nitride film 6 on the opposite side of the semiconductor layer 1 is not in direct contact with the gate insulating film 2, preferably.

The end surface of the nitride film 6 on the gate electrode 3 side is not in direct contact with the gate insulating film 2 and the gate electrode 3, preferably.

The surface of the nitride film 6 facing the semiconductor layer 1 side is not in contact with the gate insulating film 2.

The nitride film 6 and the gate insulating film 2 are adjacent to each other in the direction where the gate electrode 3 and the drain electrode 5 are aligned, and not adjacent to each other in the stacking direction of the semiconductor layer 1 and the gate electrode 3, preferable.

The portion where the gate insulating film 2 is in direct contact with the nitride film 6 does not exist between the nitride film 6 and the semiconductor layer 1 in the stacking direction of the gate electrode 3 and the semiconductor layer 1, preferably.

The surface opposite to the semiconductor layer 1 side of the nitride film is not in direct contact with the gate insulating film 2, preferably.

The surface facing the gate electrode 3 side on the semiconductor layer 1 side of the step-like portion of the nitride film 6 is in direct contact with the gate insulating film 2, preferably.

This structure of the nitride film 6 and the gate insulating film 2 is obtained by adopting a manufacturing method that reduces damage to the gate insulating film 2. The manufacturing method for the semiconductor device 100 will be described later.

The nitride film 6 includes both a highly crystalline crystal phase on the side in contact with the semiconductor layer 1 and a low-crystallinity amorphous phase. The step-like portion of the nitride film 6 includes an amorphous phase. The amorphous phase may contain a crystal phase. The crystal phase includes a crystal of nitride including aluminum (Al) or aluminum and gallium (Ga). The amorphous phase includes an amorphous of nitride including aluminum (Al) or aluminum and gallium (Ga).

The height of the step-like portion of the nitride film 6 is the sum of the thickness of the gate insulating film 2, the second insulating film 8, and the nitride film 6, and the height of the step-like portion varies depending on these thicknesses.

The highly crystalline region of the nitride film 6 that is in direct contact with the semiconductor layer 1 substantially increases the thickness of a portion of the semiconductor layer 1 near the drain electrode 5, resulting in a higher carrier density. This high carrier density is preferably advantageous for reducing on-resistance and improving collapse characteristics.

The thickness of the nitride film 6 (the thickness of the portion along the semiconductor layer 1) is preferably 1 [nm] or more and 10 [nm] or less.

The length L1 between the surface of the nitride film in contact with electrode 5 and the end surface on the gate electrode 3 side of the nitride film 6 is preferably 1% or more and 20% or less of the distance L2, more preferably 3% or more and 15% or less, and even more preferably 5% or more and 10% or less.

For increasing carrier density, a length L3 of the surface where the nitride film 6 is in contact with the semiconductor in the direction aligned with the gate electrode 3 and drain electrode 5 is preferably 0.1 [μm] or more and 10 [μm] or less, more preferably 0.3 [μm] or more and 7 [μm] or less, even more preferably 0.5 [μm] or more and 5 μm or less.

A length L4 of the step-like portion of the nitride film 6 in the direction aligned with the gate electrode 3 and drain electrode 5 is preferably 0.1 [μm] or more and 5 [μm] or less, more preferably 0.3 [μm] or more and 3 [μm] or less. and even more preferably 0.5 [μm] or more and 1.5 [μm] or less.

The length L4 is preferably 1% or more and 300% or less of the length L3, more preferably 10% or more and 200% or less of the length L3, and even more preferably 20% or more and 100% or less of the length L3.

The length L4 is preferably 1% or more and 90% or less of the length L1, more preferably 5% or more and 70% or less of the length L1, and even more preferably 10% or more and 50% or less of the length L1.

The third insulating film 7 is an interlayer dielectric (hereinafter referred to as a first interlayer dielectric 7). The first interlayer dielectric 7 is provided between the gate insulating film 2 and the fourth insulating film 11. The first interlayer dielectric 7 is provided on the nitride film 6, and is also provided between the nitride film 6 and the fourth insulating film 11. The first interlayer dielectric 7 partially covers the gate electrode 3, the source electrode 4, and the drain electrode 5. For example, the first interlayer dielectric 7 is an oxide or a nitride, such as silicon oxide (SiO₂), silicon nitride (SiN), or a high-k material. Examples of high-k materials include hafnium oxide (HfO₂).

The first interlayer dielectric 7 may be a single layer as shown in the drawings or a multilayer insulating film.

In the direction aligned with the gate electrode 3 and the drain electrode 5, the first interlayer dielectric 7 is preferably located between the gate electrode 3 and the nitride film 6 (the portion on the opposite side of the semiconductor layer 1 at the step-like portion the nitride film 6).

The first interlayer dielectric 7 is a low-density insulating film. A density of the first interlayer dielectric 7 is lower than that of the gate insulating film 2. The thickness of the first interlayer dielectric 7 is also greater than that of the gate insulating film 2, for example, 20 [nm] or more and 500 [nm] or less. In the semiconductor device 100 shown in FIG. 1, the first interlayer dielectric 7 has a step difference caused by the step-like portion of the nitride film 6. The step difference of the first interlayer dielectric 7 can be planarized by CMP (chemical mechanical polishing).

The second insulating film (buffer film) 8 is provided between the gate insulating film 2 and the nitride film 6. The buffer film 8 can be, for example, an oxide or oxynitride. The gate insulating film 2 is, for example, silicon oxide (SiO₂), silicon nitride (SiN), aluminum oxide, silicon oxynitride, or aluminum oxynitride. The buffer film 8 is a low-density insulating film.

Preferably, the surface on the semiconductor layer 1 side of the buffer film 8 is in direct contact with the gate insulating film 2. It is also preferable that the surface of the buffer film 8 on the opposite side of the semiconductor layer 1 is in direct contact with the surface of the step-like portion of the nitride film facing the semiconductor layer 1.

A part or all of the buffer film 8 may be replaced by the first interlayer dielectric 7.

The density of the buffer film 8 is preferably 2 [g/cm³] or more and 3 [g/cm³] or less. The density [g/m3] of the buffer film 8 is preferably 95% or less of that of the gate insulating film 2, and more preferably 90% or less of that of the gate insulating film 2. The thickness of the buffer film 8 is also greater than that of the gate insulating film 2. The thickness of the buffer film 8 is, for example, 20 [nm] or more and 100 nm or less.

Preferably, the end surface of the buffer film 8 on the gate electrode 3 side is located on the drain electrode 5 side compared to the end surface of the nitride film 6 on the gate electrode 3 side.

The buffer film 8 is an insulating film that may deteriorate due to post-deposition annealing (PDA) after the formation of the nitride film 6. Therefore, the area (length) where the buffer film 8 is provided on the gate insulating film 2 is preferably 0% or more and 20% or less of the area (length) from the surface on the drain electrode 5 side of the gate electrode 2 (which is located at a position within the gate insulating film 2 in line with the surface on the drain electrode 5 side of the gate electrode 2 in the stacking direction of the semiconductor layer 1 and the gate electrode 3) to the edge of the gate insulating film 2 on the drain electrode 5 side.

The fourth insulating film 11 is an interlayer dielectric (hereinafter, second interlayer dielectric 11). The second interlayer dielectric 11 is provided on the first interlayer dielectric 7. The first interlayer dielectric 7 is located between the second interlayer dielectric 11 and the gate insulating film 2. The second interlayer dielectric 11 partially covers the source electrode 4 and the drain electrode 5. For example, the second interlayer dielectric 11 is an oxide or nitride. For example, the second interlayer dielectric 11 may be silicon oxide (SiO₂), silicon nitride (SiN), or a high-k material such as hafnium oxide (HfO₂). The thickness of the second interlayer dielectric 11 is greater than that of the gate insulating film 2, for example, 50 [nm] or more and 2000 [nm] or less.

Next, referring to FIGS. 5-9, which are cross-sectional diagrams of variation of the semiconductor device 100, will be described.

FIG. 5 shows a schematic diagram of a semiconductor device 101 that has the same or similar sectional location as FIG. 1. The difference between the semiconductor device 103 in FIG. 5 and the semiconductor device 100 is that a crystal phase 6a and an amorphous phase 6b of the nitride film 6 are distinguished. Although the boundary between the crystal phase 6a and the amorphous phase 6b may not be clear, as shown in the schematic diagram in FIG. 5, the nitride film 6 on the semiconductor layer 1 side becomes the crystal phase 6a. This is because the portion of the nitride film 6 that grows from the semiconductor layer 1 becomes the crystal phase 6a, and the portion grown from outside the semiconductor layer 1 becomes the amorphous phase 6b. The amorphous phase 6b may contain a part of crystals such as AlN.

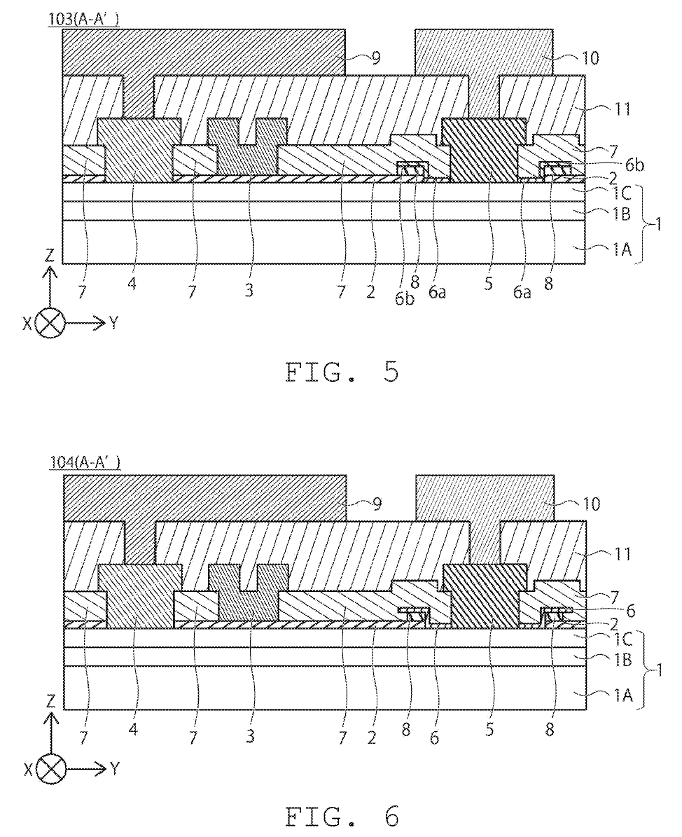

FIG. 6 shows a schematic diagram semiconductor device 102 t that has the same or similar sectional location as FIG. 1. The difference between the semiconductor device 104 in FIG. 6 and the semiconductor device 100 is that a part of the first interlayer dielectric 7 is provided between the nitride film 6 and the gate insulating film 2. The buffer film 8 located under the nitride film 6 may be partly or entirely removed during the manufacturing process. In such a case, as shown in the semiconductor device 102 of the schematic diagram in FIG. 6, the first interlayer dielectric 7 is provided on the gate electrode 3 side between the nitride film 6 and the gate insulating film 2.

FIG. 7 shows a schematic diagram of a semiconductor device 103 that has the same or similar sectional location as FIG. 1. The difference between the semiconductor device 104 in FIG. 7 and the semiconductor device 100 is that the first interlayer dielectric 7 is provided entirely between the nitride film 6 and the gate insulating film 2, and a portion of the step-like portion of the nitride film 6 along the gate insulating film 2 is inclined in the stacking direction of the semiconductor layer 1 and the gate electrode 3. The buffer film 8 located under the nitride film 6 may be partly or entirely removed during the manufacturing process. In such a case, as shown in the semiconductor device 102 of the schematic diagram in FIG. 7, the first interlayer dielectric 7 is provided over the entire gap between the nitride film 6 and the gate insulating film 2.

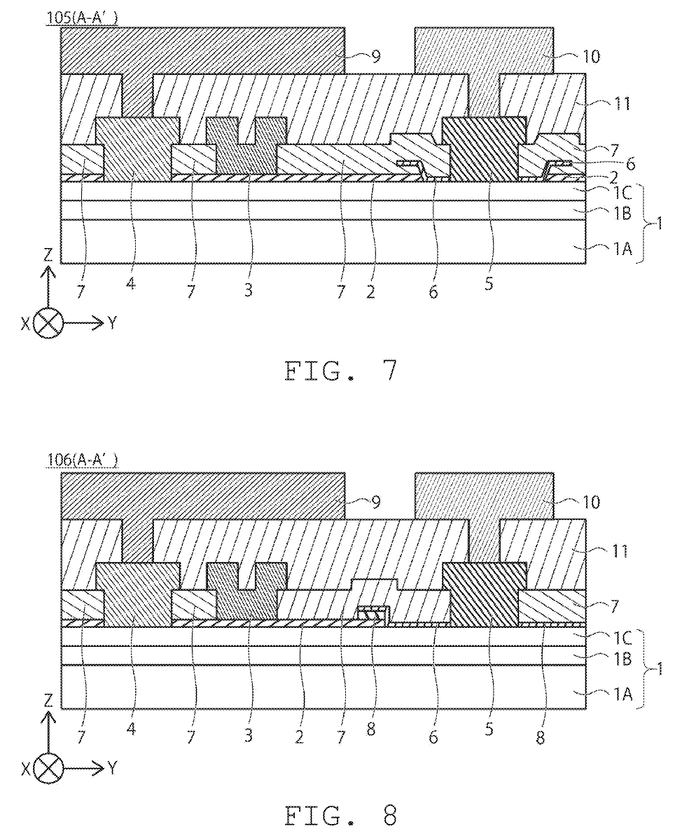

FIG. 8 shows a schematic diagram of a semiconductor device 106 that has the same or similar sectional location as FIG. 1. The difference between the semiconductor device 106 in FIG. 8 and the semiconductor device 100 is that the step-like portion of the nitride film 6 is located between the source FP electrode 9 and the drain FP electrode 10. The length of the step-like portion of the nitride film 6 and the length of the portion where the nitride film 6 is in contact with the semiconductor layer 1 can be changed as shown in FIG. 8, for example. The shape and position of the nitride film 6 can be changed according to the required specifications while considering carrier density etc.

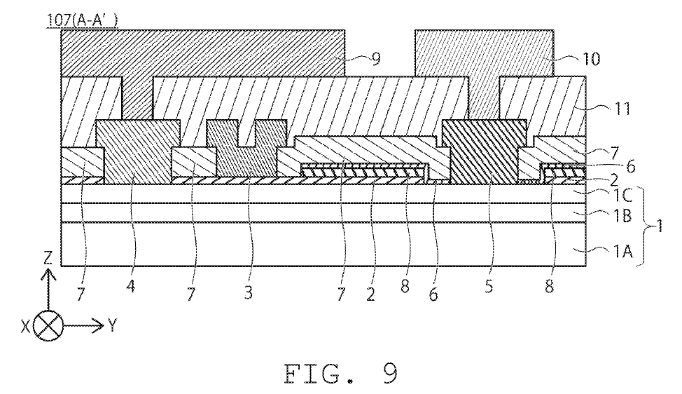

FIG. 9 shows a schematic diagram of a semiconductor device 107 that has the same or similar sectional location as FIG. 1. The semiconductor device 107 in FIG. 9 differs from the semiconductor device 100 in that the step-like portion of the nitride film 6 is provided closer to the gate electrode 3. The shape and position of the nitride film 6 may be changed according to the required specifications while considering carrier density, etc. Also, when a source FP electrode (not shown in drawings) is provided between the gate electrode 3 and the drain electrode 5, it is preferable that this source FP electrode is not in direct contact with the nitride film 6.

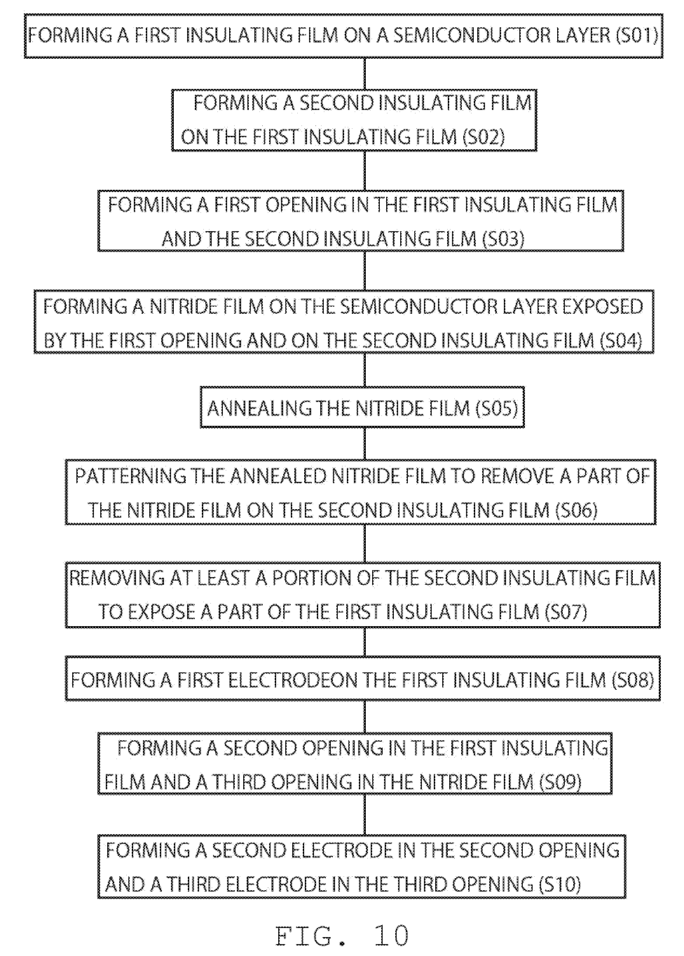

Next, the manufacturing method for the semiconductor device 100 will be described. A flowchart of the manufacturing method for the semiconductor device 100 is shown in FIG. 10. Referring to diagrams from FIGS. 11-22, the manufacturing method for the semiconductor device 100 will be described.

The manufacturing method for the semiconductor device 100 comprises: forming a first insulating film 2 on a semiconductor layer 1 (S01); forming a second insulating film 8 on the first insulating film 2 (S02); forming a first opening V1 in the first insulating film 2 and the second insulating film 8 (S03); forming a nitride film 6 on the semiconductor layer 1 exposed by the first opening V1 and on the second insulating film 8 (S04); annealing the nitride film 6 (S05); patterning the annealed nitride film 6 to remove a part of the nitride film 6 on the second insulating film 8 (S06); removing at least a portion of the second insulating film 8 to expose a part of the first insulating film 2 (S07); forming a first electrode 3 on the first insulating film 2 (S08); forming a second opening V2 in the first insulating film 2 and a third opening V3 in the nitride film 6 (S09); and forming a second electrode 4 in the second opening V2 and a third electrode 5 in the third opening V3 (S10).

Referring to the schematic diagram of FIG. 11, the process (S01) of forming the first insulating film 2 on the semiconductor layer 1 and the process (S02) of forming the second insulating film 8 on the first insulating film 2) will be described. By providing the gate insulating film 2 on the semiconductor layer 1, a member 110 is obtained in which the gate insulating film 2 is provided on the semiconductor layer 1 and the buffer film 8 is provided on the gate insulating film 2. The buffer film 8 is preferably provided on the entire surface of the gate insulating film 2, and is preferably provided on the entire surface of the gate insulating film 2 in the device region.

For example, the gate insulating film 2 with a high density is formed on the semiconductor layer 1 by LP-CVD (Low-Pressure Chemical Vapor Deposition) method.

For example, the buffer film 8 with a low density is formed on the gate insulating film 2 by a PE-CVD (Plasma-Enhanced Chemical Vapor Deposition) method.

Referring to the schematic diagram of FIG. 12, the process (S03) of forming the first opening V1 in the first insulating film (gate insulating film) 2 and the second insulating film (buffer film) 8 will be described. The first opening V1 is formed in the gate insulating film 2 and the buffer film 8 on the semiconductor layer 1 of the member 110 shown in FIG. 11 where the drain electrode 5 and the nitride film 6 which contacts with the semiconductor layer 1 are to be provided to obtain a member 111 shown in FIG. 12. The opening area of the first opening V1 changes mainly depending on the area of the nitride film 6 contacting the semiconductor layer 1.

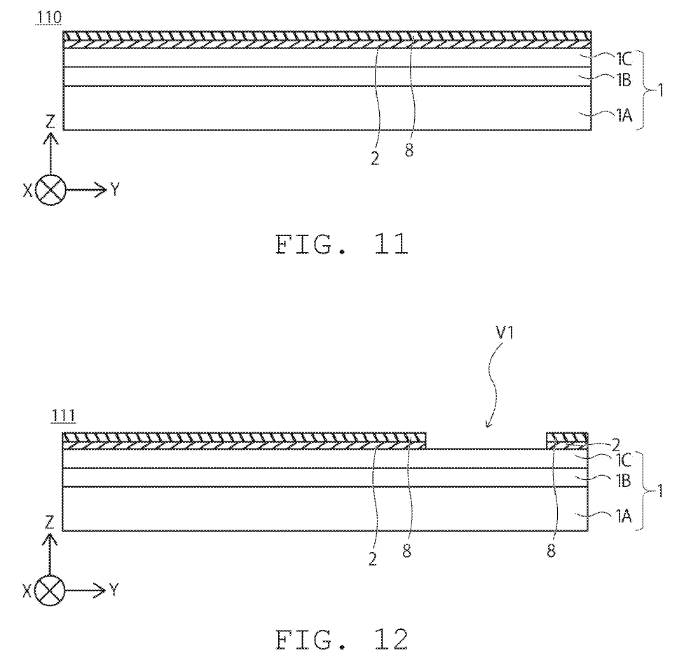

Referring to the schematic diagram of FIG. 13, the process (S04) of forming the nitride film 6 on the semiconductor layer 1 exposed by the first opening V1 and on the second insulating film 8 (S04). The nitride film 6 is formed on the portion opened by the first opening V1 in FIG. 12 a member 111 and the buffer layer 8 which is provided on the uppermost surface of the semiconductor layer 1, to obtain member 112 shown in FIG. 12. The nitride film 6 is provided at the ross-section of the first opening V1 of the gate insulating film 2 but not on the main surface of the gate insulating film 2 along the semiconductor layer 1.

Since a portion where the gate insulating film 2 and the buffer film 8 are stacked is included on the semiconductor layer 1, a step difference arises between the portion of the nitride film 6 formed on the stacked member of the gate insulating film 2 and the buffer film 8 and the portion of the nitride film 6 formed on the semiconductor layer 1. Therefore, the step-like portion is formed. When the nitride film 6 is formed before forming the gate insulating film 2, the step-like portion of the nitride film 6 would not be formed.

When the nitride film 6 is formed directly above the gate insulating film 2 results in the formation of the step-like portion. This process makes the nitride film 6 in the stacking direction of the semiconductor layer 1 and the gate electrode 3 of the semiconductor device 100 to be in direct contact with the gate insulating film 2 overall. Therefore, such semiconductor device does not include a portion where the step-like portion of the nitride film 6 is separated from the gate insulating film 2.

Referring to the schematic diagram of FIG. 14, the process (S05) of annealing the nitride film 6 and the process (S06) of patterning the annealed nitride film 6 to remove the part of the nitride film 6 on the second insulating film 8 will be described. The member 112 shown in FIG. 13 is annealed. Preferably, at least the gate insulating film 2 in the device region is covered by the buffer film 8 and the nitride film 6 during annealing, and the gate insulating film 2 in the device region is not exposed during annealing. When the gate insulating film 2 is exposed during annealing, the gate insulating film 2 may deteriorate due to annealing damage. By covering the gate insulating film 2 with the buffer film 8 and the nitride film 6 during annealing, deterioration of the gate insulating film 2 can be reduced while annealing can be performed.

Annealing increases the crystallinity of the nitride film 6, improving the film quality. High-quality nitride film 6 preferably leads to an increase in carrier density. For example, annealing may be carried out at 900 [° C] for 30 minutes in a nitrogen gas atmosphere.

It is preferable that the gate insulating film 2 provided between the side surface (starting point) of the gate electrode 3 and a location (ending point) of at least 0.5 [μm] (preferably 1 [μm], more preferably 1.5 [μm]) from the starting point toward the source electrode 4 in the direction aligned with the gate electrode 3 and the drain electrode 5, is covered by the buffer film 8 during annealing. It is also preferable that, in the direction from the gate electrode 3 from the starting point toward the drain electrode 5, the gate insulating film 2 provided between the side surface (starting point) of the gate electrode 3 and a location of at least 50% (preferably 65%, more preferably 80%) (ending point) of a distance L5 between the gate electrode 3 and the source electrode 4 from the starting point to the source electrode 4 is covered by the buffer film 8 during annealing. It is also preferable that the gate insulating film 2 provided between the side surface (starting point) of the gate electrode 3 and the end face (ending point) of the source electrode 4 is covered by the buffer film 8 during annealing. Covering most of the gate insulating film 2 with the buffer film 8 reduces degradation of the insulating film caused by annealing from reducing the function as a gate insulating film.

It is preferable that the gate insulating film 2 provided between the side surface (starting point) of the gate electrode 3 and a location (ending point) of at least 5 [μm] (preferably 10 [μm], more preferably 15 [μm]) from the starting point toward the drain electrode 5 in the direction aligned with the gate electrode 3 and the drain electrode 5, is covered by the buffer film 8 during annealing. It is also preferable that the gate insulating film 2 provided between the side surface (starting point) of the gate electrode 3 and a location (ending point) at least 50% (preferably 65%, more preferably 80%) of the distance L2 from the starting point toward the drain electrode 5 is covered by the buffer film 8 during annealing. It is preferable that, the gate insulating film 2 provided between the side surface (starting point) of the gate electrode 3 and a location (ending point) where the lower end of the surface of the nitride film 6 on the drain electrode 5 side facing the gate electrode 3 which is in direct contact with the semiconductor layer 1 (the area of the buffer film 8 provided between the the edge surface on the drain electrode 5 side of the gate electrode (starting point) and a length of "L2-L3" (subtracted L2 from L3) from the starting point toward the drain electrode), is covered by the buffer film 8 during annealing. Removing most of the buffer film 8 covered with the gate insulating film 2 in subsequent process, reduces degradation of the insulating film caused by annealing from reducing the function as a gate insulating film.

After the annealing, the nitride film 6 is patterned to remove part of the nitride film 6 on the buffer film 8, obtaining a member 113 shown in FIG. 14. During patterning, the nitride film 6 at the portion where the drain electrode 5 is formed is removed, the nitride film 6 outside the region of the portion where the drain electrode 5 is formed is left, and the nitride film 6 at the regions where the gate electrode 3 and source electrode 4 are formed is removed. Preferably, part of the step-like portion and the portion of the nitride film 6 in direct contact with the semiconductor layer 1 remain when patterning the nitride film 6. When the entire step-like portion is removed, the nitride film 6 in direct contact with the semiconductor layer 1 is easily removed as well. Therefore, it is preferable that, at least in the device region before and after patterning the nitride film 6, the semiconductor layer 1 between the gate electrode 3 and the drain electrode 5 is overall covered by the gate insulating film 2 (more specifically, during annealing, the end surface of the drain electrode 5 side of the gate insulating film 2 is covered by the nitride film 6, the entire surface on the semiconductor layer 1 side is in direct contact with the semiconductor layer 1, and the entire surface on the opposite side from the semiconductor layer 1 side is covered by the buffer film 8) and the nitride film 6.

Performing patterning of the nitride film 6 after annealing increases the degradation of the gate insulating film 2, which reduces the effect of providing the buffer film 8. Therefore, it is preferable to perform patterning of the nitride film 6 after annealing.

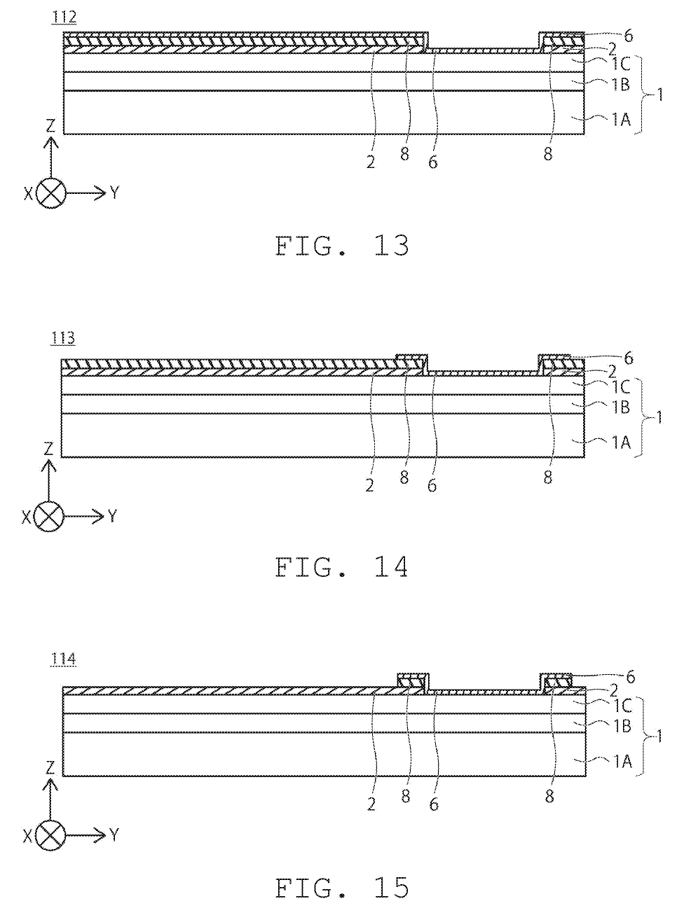

Referring to the schematic diagram of FIG. 15, the process (S07) of removing at least the portion of the second insulating film 8 to expose the part of the first insulating film 2 will be described. To remove the buffer film 8 of the member 113 shown in FIG. 14, wet etching or the like is performed as an example. The buffer film 8 with a lower density than the gate insulating film 2 is selectively removed due to the density difference. As a result, the member 114 shown in FIG. 15 is obtained. Depending on the conditions of the etching solution, etc., the step-like portion of the buffer film 8 may also dissolve. Therefore, depending on the progress of the etching, the semiconductor device 100 of FIG. 1, the semiconductor device 105 of FIG. 6, or the semiconductor device 106 of FIG. 7 or the like can be obtained.

It should be noted that although the step-like portion is excluded in the diagram, the buffer film 8 is completely removed. However, when it is not a layered structure, some of the buffer film 8 may remain on the gate insulating film 2 as islands. In this specification, the description does not take into account the island-shaped remaining buffer film 8.

In the process (S06) of patterning the annealed nitride film 6 and removing a part of the nitride film 6 on the second insulating film (buffer film) 8, when a part of the gate insulating film 2 is removed, the gate insulating film 2 is likely to be dissolved when removing the buffer film 8. Therefore, it is preferable to leave the nitride film 6 of the step-like portion.

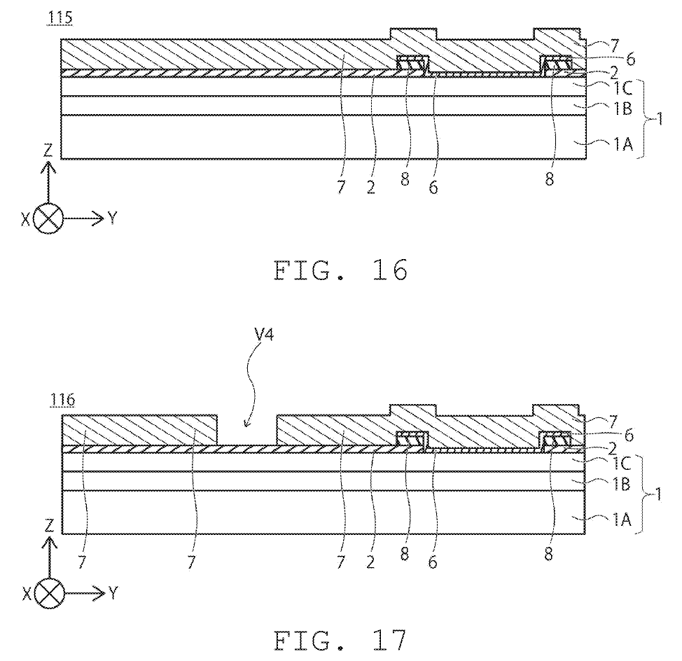

Next, the first interlayer dielectric 7 is formed to obtain a member 115 shown in FIG. 16. Then, a fourth opening V4 for forming the gate electrode 3 is formed to obtain a member 116 shown in FIG. 17.

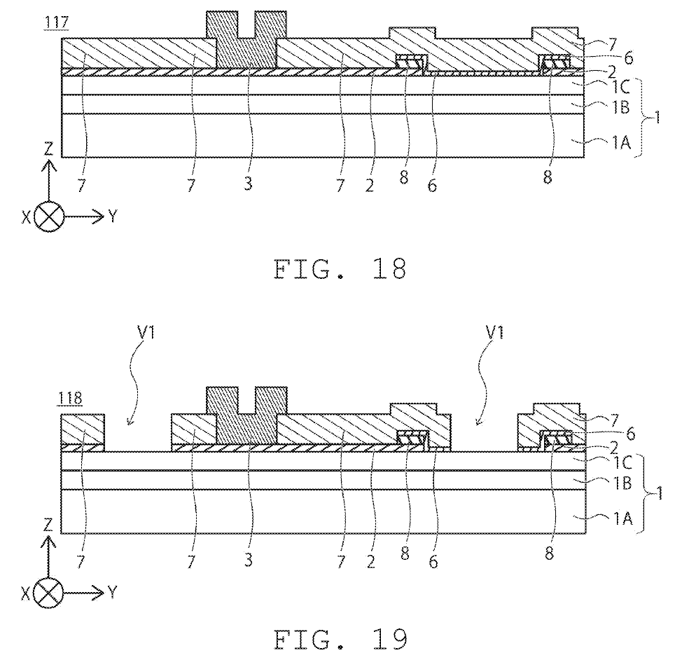

Referring to the schematic diagram of FIG. 18, the process (S08) of forming the first electrode 3 on the first insulating film 2 (S08) will be described. The gate electrode 3 is formed on the gate insulating film 2 covered by the buffer film 8 during annealing to obtain a member 117 shown in FIG. 18. When forming the gate electrode 3, an electrode layer may be formed, followed by forming an interlayer dielectric and forming an opening again, and then forming a field plate electrode portion. It is preferable that the first interlayer dielectric 7 is provided on the gate insulating film 2 when annealing is performed during the formation of the gate electrode 3.

Referring to the schematic diagram of FIG. 19, the process (S09) of forming the second opening V2 in the first insulating film 2 and the third opening V3 in the nitride film 6 will be described. The second opening V2 for the source electrode 4 is formed on the member 117 shown in FIG. 18, and the third opening V3 for the drain electrode 5 is formed to obtain a member 118 shown in FIG. 17. The second openings V2 and third openings V3 are also provided on the first interlayer dielectric 7.

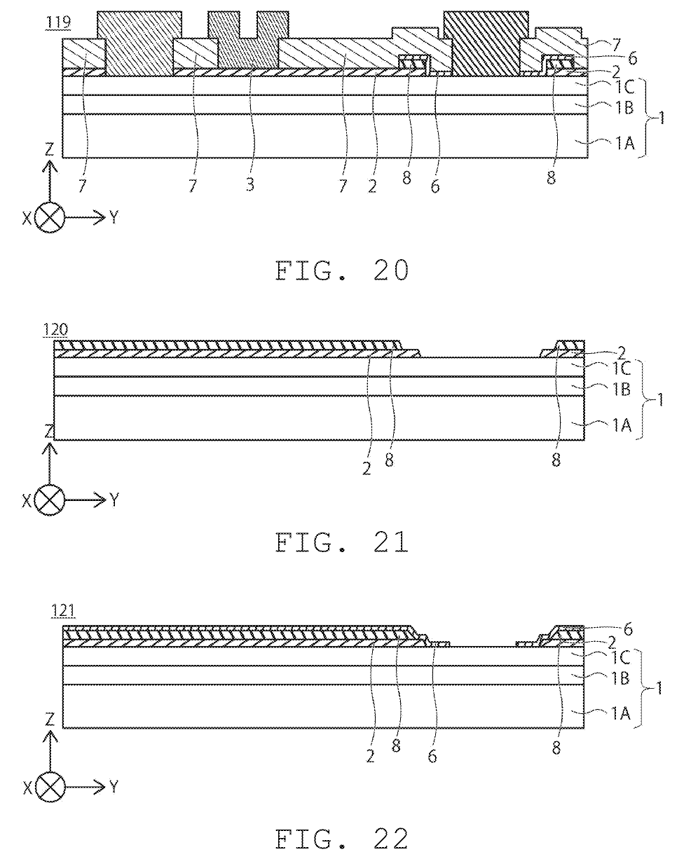

Referring to the schematic diagram of FIG. 20, the process (S10) for forming the second electrode 4 in the second opening V2 and the third electrode 5 in the third opening V3 will be described. Electrodes are formed in the second opening V2 and the third opening V3 of the member 118 shown in FIG. 19, so that the source electrode 4 and drain electrode 5 are formed, resulting in a member 119 shown in FIG. 20. It is preferable that the first interlayer dielectric 7 is provided on the gate insulating film 2 when annealing is performed during the formation of the source electrode 4 and the drain electrode 5. Then, the second interlayer dielectric 11, the source FP electrode 9 and the drain FP electrode 10 are formed to obtain the semiconductor device 100.

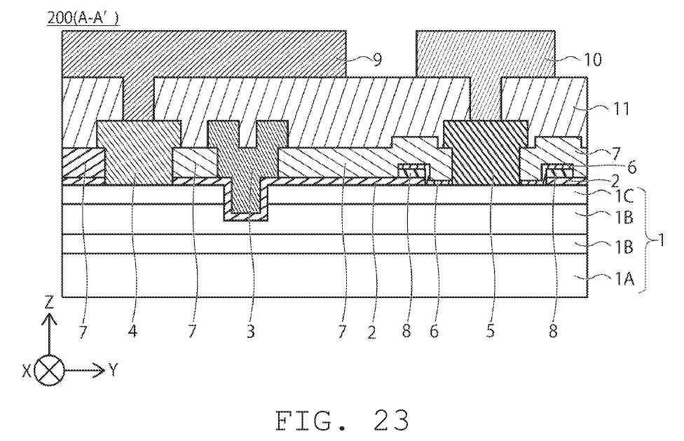

Furthermore, in the process (S03) for forming the first opening V1 in the first insulating film (gate insulating film) 2 and the second insulating film (buffer film) 8, the surface of the gate insulating film 2 on the side where the drain electrode 5 is formed may be exposed depending on the processing conditions of the gate insulating film 2 and the buffer film 8. As shown in FIG. 21, the member 119, when the nitride film 6 is formed on the member 119, a member 120 shown in FIG. 22 is obtained. This results in a semiconductor device such as the semiconductor device 101 of FIG. 3 or the semiconductor device 102 of FIG. 4 where the nitride film 6 rides up onto the gate insulating film 2 on the drain electrode 5 side.

When the semiconductor device 101 shown in FIG. 3 or the semiconductor device 102 shown in FIG. 4 is obtained, a portion of the gate insulating film 2 on the side where the nitride film 6 and the semiconductor layer 1 are in direct contact with each other is not covered by the buffer film 8 during the annealing process (S05) of the nitride film 6. However, because the ratio of the portion of the gate insulating film 2 that is not covered by the buffer film 8 to the total area of the gate insulating film 2 on the side where the nitride film 6 and the semiconductor layer 1 are in direct contact with each other is 5% or less, preferably 4% or less, and more preferably 3% or less during the annealing process (S05) of the nitride film 6, the portion that deteriorates is sufficiently separated from the gate electrode 3. In other words, since the gate insulating film 2 in the region where the gate electrode 3 is formed is mostly covered by the buffer film 8, even when there is a portion of the gate insulating film 2 that is not covered by the buffer film 8, the annealing process (S03) can be employed as a method for obtaining a highly reliable semiconductor device.

By employing the manufacturing method of this embodiment, damage to the gate insulating film 2 can be reduced, and both high reliability and high carrier density can be achieved. As a result of the manufacturing method, the step-like portion is formed in the nitride film 6.

### Second Embodiment

A second embodiment relates to a semiconductor device and a manufacturing method for a semiconductor device. The semiconductor device of the second embodiment is a variation of the semiconductor device 100 of the first embodiment. Descriptions common to both the semiconductor device 200 of the second embodiment and the semiconductor device 100 of the first embodiment are omitted. The contents described in the second embodiment can also be applied to the first embodiment.

FIG. 23 shows a schematic diagram of the semiconductor device 200 according to the second embodiment. The semiconductor device 200 has a trench-type gate electrode 3 for the gate electrode 3, and a buffer layer 1D between the substrate 1A and the channel layer 1B, except for these differences, the semiconductor device 200 is similar to the semiconductor device 100.

The second embodiment shares with the first embodiment that the nitride film 6 is not provided between the gate insulating film 2 and the semiconductor layer 1 in the trench; this configuration enables a reduction in degradation of the gate insulating film 2, thereby allowing for an increase in carrier density. In view of increasing the carrier density of normally-off type GaN HEMTs with trench-type gate electrodes, adopting the configuration according to this embodiment is preferred.

Next, the manufacturing method for the semiconductor device 200 includes an additional step of forming a trench before forming the gate insulating film 2. The manufacturing method for the semiconductor device 200 is similar to that of the semiconductor device 100 except for the added step mentioned above. By employing the manufacturing method according to this embodiment, damage to the gate insulating film can be reduced and carrier density can be increased.

In the specification, some elements are represented only by chemical symbols for elements.

Hereinafter, technical clauses of embodiments are additionally noted.

### Clause 1

A semiconductor device comprising:

a semiconductor layer;

a first insulating film provided on the semiconductor layer;

a first electrode provided on the first insulating film;

a second electrode provided on the semiconductor layer;

a third electrode provided on the semiconductor layer; and

a nitride film provided on the semiconductor layer on the second electrode side between the first electrode and the second electrode, wherein

the nitride film includes a step-like portion on the first electrode,

the nitride film and the first insulating film are arranged in a stacking direction of the semiconductor layer and the first electrode,

the nitride film includes a portion which is in direct contact with the semiconductor layer, and

a portion of the step-like portion is physically separated from the first insulating film in the stacking direction.

### Clause 2

A semiconductor device comprising:

a semiconductor layer;

a first insulating film provided on the semiconductor layer;

a first electrode provided on the first insulating film;

a second electrode provided on the semiconductor layer;

a third electrode provided on the semiconductor layer; and

a nitride film provided on the semiconductor layer on the second electrode side between the first electrode and the second electrode, wherein

the nitride film and the first insulating film are arranged in a stacking direction of the semiconductor layer and the first electrode,

the nitride film includes a portion which is in direct contact with the semiconductor layer,

the nitride film on the first electrode side has a riding-up portion that rides up onto the first insulating film on the third electrode side in the stacking direction, and

a length of the riding-up portion in a direction where the first electrode and the third electrode are aligned is more than 0% and 5% or less of a distance between an end surface on the third electrode side of the first electrode and an end surface on the first electrode side of the third electrode.

### Clause 3

The semiconductor device according to clause 1 or 2, wherein

the step-like portion is physically separated from the first insulating film in the stacking direction.

### Clause 4

The semiconductor device according to any one of clauses 1 to 3, wherein

a portion where a surface of the first insulating film facing the nitride film side and a surface of the step-like portion of the nitride film facing the first insulating film are separated from each other in the stacking direction is included.

### Clause 5

The semiconductor device according to any one of clauses 1 to 4, wherein

a height difference of the step-like portion is 1 or more times and 5 or less times thicker than a thickness of the first insulating film.

### Clause 6

The semiconductor device according to any one of clauses 1 to 5, wherein

the nitride film is a nitride film including aluminum or aluminum and gallium.

### Clause 7

The semiconductor device according to any one of clauses 1 to 6, wherein

the step-like portion includes an amorphous phase.

### Clause 8

The semiconductor device according to any one of clauses 1 to 7, wherein

the nitride film is in direct contact with the first semiconductor layer and the third electrode.

### Clause 9

The semiconductor device according to any one of clauses 1 to 8, wherein

the portion where the nitride film is in direct contact with the semiconductor layer is located between the first insulating film and the third electrode in a direction where the first electrode and the third electrode are aligned.

### Clause 10

The semiconductor device according to any one of clauses 1 to 9, wherein

a surface of the nitride film opposite to the semiconductor layer side is not in direct contact with the first insulating film.

### Clause 11

The semiconductor device according to any one of clauses 1 to 10, wherein

an end surface of the nitride film on the first electrode side is not in direct contact with the first insulating film and the first electrode.

### Clause 12

The semiconductor device according to any one of clauses 1 to 10, wherein

an end surface of the nitride film on the first electrode side is not in direct contact with the first insulating film, and

the end surface of the nitride film on the first electrode side is not also in direct contact with the first electrode.

### Clause 13

The semiconductor device according to any one of clauses 1 to 12, wherein

a surface of the nitride film on the semiconductor layer side is not in direct contact with the first insulating film.

### Clause 14

The semiconductor device according to any one of clauses 1 to 13, further comprising an insulating layer provided between the nitride film and the first insulating film in the stacking direction with a lower density than the first insulating film.

### Clause 15

The semiconductor device according to any one of clauses 1 to 12, wherein

the first electrode is a trench-type electrode.

### Clause 16

The semiconductor device according to clause 2, wherein

the nitride film further includes a portion separated from the first insulating film located further on the first electrode side from the riding-up portion.

### Clause 17

The semiconductor device according to any one of clauses 1 to 16, wherein

the nitride film is along the side surface of the third electrode side of the first insulating film, and

a portion where the nitride film is along the side surface of the third electrode side of the first insulating film includes one or more selected from the group consisting of a part extending in the stacking direction, a part inclined with respect to the stacking direction, and a part curved with respect to the stacking direction.

### Clause 18

A manufacturing method for a semiconductor device comprises:

forming a first insulating film on a semiconductor layer;

forming a second insulating film on the first insulating film;

forming a first opening in the first insulating film and the second insulating film;

forming a nitride film on the semiconductor layer exposed by the first opening and on the second insulating film;

annealing the nitride film;

patterning the annealed nitride film to remove a part of the nitride film on the second insulating film;

removing at least a portion of the second insulating film to expose a part of the first insulating film;

forming a first electrode on the first insulating film;

forming a second opening in the first insulating film and a third opening in the nitride film; and

forming a second electrode in the second opening and a third electrode in the third opening.

### Clause 19

The method according to clause 18, wherein

the first insulating film is denser than the second insulating film, and

wet-etching is performed to remove the second insulating film.

### Clause 20

The method according to clause 18 or 19, wherein

the first insulating film is covered with the second insulating film during the annealing or a portion of the first insulating film on the side where the nitride film and the semiconductor layer are in direct contact with each other is not covered by the second film during the annealing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer;
a first insulating film provided on the semiconductor layer;
a first electrode provided on the first insulating film;
a second electrode provided on the semiconductor layer;
a third electrode provided on the semiconductor layer; and
a nitride film provided on the semiconductor layer on the second electrode side between the first electrode and the second electrode, wherein
the nitride film includes a step-like portion on the first electrode,
the nitride film and the first insulating film are arranged in a stacking direction of the semiconductor layer and the first electrode,
the nitride film includes a portion which is in direct contact with the semiconductor layer, and
a portion of the step-like portion is physically separated from the first insulating film in the stacking direction.

2. The semiconductor device according to claim 1, wherein
the step-like portion is physically separated from the first insulating film in the stacking direction.

3. The semiconductor device according to claim 1, wherein
a portion where a surface of the first insulating film facing the nitride film side and a surface of the step-like portion of the nitride film facing the first insulating film are separated from each other in the stacking direction is included.

4. The semiconductor device according to claim 1, wherein
a height difference of the step-like portion is 1 or more times and 5 or less times thicker than a thickness of the first insulating film.

5. The semiconductor device according to claim 1, wherein
the nitride film is a nitride film including aluminum or both aluminum and gallium.

6. The semiconductor device according to claim 1, wherein
the step-like portion includes an amorphous phase.

7. The semiconductor device according to claim 1, wherein
the nitride film is in direct contact with the first semiconductor layer and the third electrode.

8. The semiconductor device according to claim 1, wherein
the portion where the nitride film is in direct contact with the semiconductor layer is located between the first insulating film and the third electrode in a direction where the first electrode and the third electrode are aligned.

9. The semiconductor device according to claim 1, wherein
a surface of the nitride film opposite to the semiconductor layer side is not in direct contact with the first insulating film.

10. The semiconductor device according to claim 1, wherein
an end surface of the nitride film on the first electrode side is not in direct contact with the first insulating film and the first electrode.

11. The semiconductor device according to claim 1, wherein
a surface of the nitride film on the semiconductor layer side is not in direct contact with the first insulating film.

12. The semiconductor device according to claim 1, further comprising an insulating layer provided between the nitride film and the first insulating film in the stacking direction with a lower density than the first insulating film.

13. A semiconductor device comprising:
a semiconductor layer;
a first insulating film provided on the semiconductor layer;
a first electrode provided on the first insulating film;
a second electrode provided on the semiconductor layer;
a third electrode provided on the semiconductor layer; and
a nitride film provided on the semiconductor layer on the second electrode side between the first electrode and the second electrode, wherein
the nitride film and the first insulating film are arranged in a stacking direction of the semiconductor layer and the first electrode,
the nitride film includes a portion which is in direct contact with the semiconductor layer,
the nitride film on the first electrode side has a riding-up portion that rides up onto the first insulating film on the third electrode side in the stacking direction, and
a length of the riding-up portion in a direction where the first electrode and the third electrode are aligned is more than 0% and 5% or less of a distance between an end surface on the third electrode side of the first electrode and an end surface on the first electrode side of the third electrode.

14. The semiconductor device according to claim 13, wherein
the portion where the nitride film is in direct contact with the semiconductor layer is located between the first insulating film and the third electrode in a direction where the first electrode and the third electrode are aligned.

15. The semiconductor device according to claim 13, wherein
an end surface of the nitride film on the first electrode side is not in direct contact with the first insulating film and the first electrode.

16. The semiconductor device according to claim 13, wherein
the nitride film further includes a portion separated from the first insulating film located further on the first electrode side from the riding-up portion.

17. The semiconductor device according to claim 13, wherein
the nitride film is along the side surface of the third electrode side of the first insulating film, and
a portion where the nitride film is along the side surface of the third electrode side of the first insulating film includes one or more selected from the group consisting of a part extending in the stacking direction, a part inclined with respect to the stacking direction, and a part curved with respect to the stacking direction.

18. A manufacturing method for a semiconductor device comprises:
forming a first insulating film on a semiconductor layer;
forming a second insulating film on the first insulating film;
forming a first opening in the first insulating film and the second insulating film;
forming a nitride film on the semiconductor layer exposed by the first opening and on the second insulating film;
annealing the nitride film;
patterning the annealed nitride film to remove a part of the nitride film on the second insulating film;
removing at least a portion of the second insulating film to expose a part of the first insulating film;
forming a first electrode on the first insulating film;
forming a second opening in the first insulating film and a third opening in the nitride film; and
forming a second electrode in the second opening and a third electrode in the third opening.

19. The method according to claim 18, wherein
the first insulating film is denser than the second insulating film, and
wet-etching is performed to remove the second insulating film.

20. The method according to claim 18, wherein
the first insulating film is covered with the second insulating film during the annealing or a portion of the first insulating film on the side where the nitride film and the semiconductor layer are in direct contact with each other is not covered by the second film during the annealing.
